(19) United States
(12) Patent Application Publication
(10) Pub. No.: US 2011/0058692 A1
(43) Pub. Date: Mar. 10, 2011

(54) AUDIO OUTPUT DEVICES

(75) Inventor: Chih-Haur Huang, Tainan County (TW)

(73) Assignee: HIMAX MEDIA SOLUTIONS, INC., Tainan County (TW)

(21) Appl. No.: 12/555,942

(22) Filed: Sep. 9, 2009

(51) Int. Cl. H03F 99/00

(52) U.S. Cl. 381/120

(57) ABSTRACT

An audio output device is provided and includes a power source, a controller, a signal generating circuit, and a first amplifier. The power source provides a supply voltage signal. The controller receives the supply voltage signal. The controller further compares the supply voltage signal with a threshold voltage signal and generates a control signal according to the comparison result. The signal generating circuit generates a first analog signal. The first amplifier receives the first analog signal and generates a first amplified signal according to the control signal.

### BACKGROUND OF THE INVENTION

1. Field of the Invention

The invention relates to an audio output device, and more particularly to an audio output device which eliminates noises.

2. Description of the Related Art

FIG. 1 shows a conventional audio output device 1. A power source 10 provides a 12V voltage. Two lower voltages are obtained by converting the 12V voltage, by two regulators 11 and 12, into a 5V voltage and a 3.3V voltage. The 3.3V voltage is provided to a processor 13 and a digital-to-analog converter (DAC) 14, while the 5V voltage is provided to an amplifier 15. Assume that the audio output device 1 is working, and a speaker 16 is operating to produce source according to analog signals from the amplifier 15. When the power source 10 is turned off and stops providing the 12V voltage, for example when the electric plug of the audio output device 1 is pulled out of the socket, pump noise is produced through the amplifier 15 and the speaker 16, degrading auditory effect.

Thus, it is desired to provide an audio output device which can reduce pump noise when a power source of the audio output device is turned off.

### BRIEF SUMMARY OF THE INVENTION

An exemplary embodiment of an audio output device comprises a power source, a controller, a signal generating circuit, and a first amplifier. The power source provides a supply voltage signal. The controller receives the supply voltage signal. The controller further compares the supply voltage signal with a threshold voltage signal and generates a control signal according to the comparison result. The signal generating circuit generates a first analog signal. The first amplifier receives the first analog signal and generates a first amplified signal according to the control signal.

Another exemplary embodiment of an audio output device comprises a power source, a controller, a signal generating circuit, and a first amplifier. The power source provides a supply voltage signal. The signal generating circuit generates a first analog signal. The first amplifier receives the first analog signal. The controller receives the supply voltage signal. The controller further compares the supply voltage signal with a threshold voltage signal and generates a control signal according to the comparison result. When a level of the supply voltage signal is higher than a level of the threshold voltage signal, the first amplifier generates a first amplified signal according to the control signal. When the level of the supply voltage signal is lower than the level of the threshold voltage signal, the first amplifier stops generating the first amplified signal according to the control signal.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a conventional audio output device;

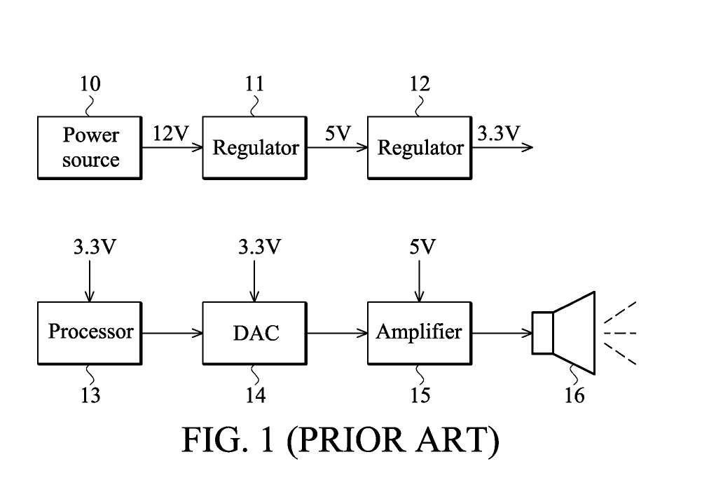

FIG. 2 shows an exemplary embodiment of an audio output device;

FIG. 3 shows an exemplary embodiment of the amplifier in FIG. 2;

FIG. 4 shows an exemplary embodiment of the controller in FIG. 2; and

FIG. 5 shows another exemplary embodiment of an audio output device.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

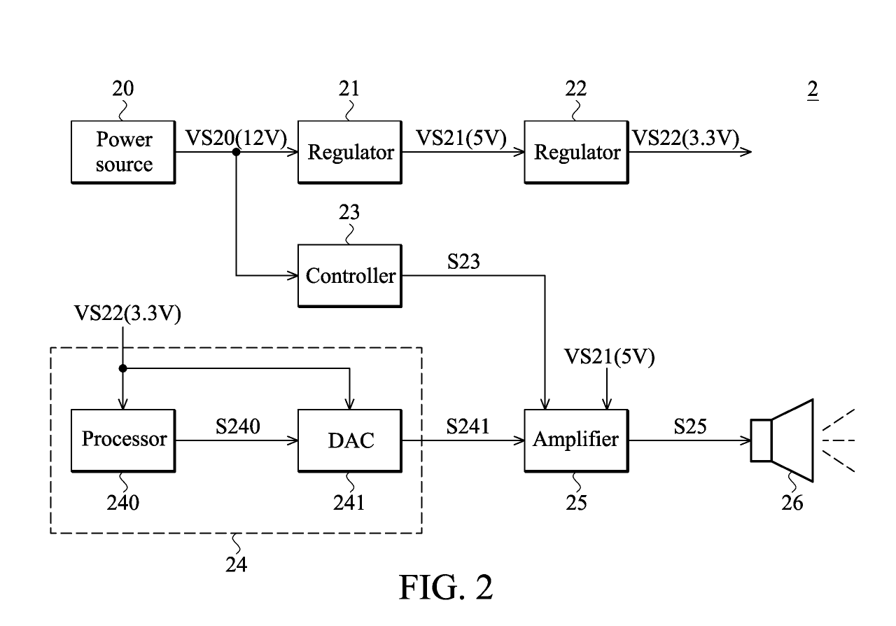

Audio output devices are provided. In an exemplary embodiment of an audio output device in FIG. 2, an audio output device 2 comprises a power source 20, regulators 21 and 22, a controller 23, a signal generating circuit 24, an amplifier 25, and a speaker 26. The power source 20 provides a supply voltage signal VS20. In the embodiment, when the power source 20 is turned on (for example, when the electric plug of the audio output device 2 is put into a socket), the supply voltage signal VS20 has a level of 12V. The regulator 21 receives the supply voltage signal VS20 of 12V and generates a voltage signal VS21 of 5V. The regulator 22 receives the voltage signal VS21 of 5V and generates a voltage signal VS22 of 3.3V. The voltage signal VS21 of 5V is provided to the amplifier 25, and the voltage signal VS22 of 3.3V is provided to the signal generating circuit 24. The controller 23 also receives the supply voltage signal VS20. The controller 23 compares the supply voltage signal VS20 with a threshold voltage signal VTH and generates a control signal S23 according to the comparison result for controlling the amplifier 25. The level of the threshold voltage signal VTH is set to be lower than the level of the supply voltage signal VS20. In the embodiment, the level of the threshold voltage signal VTH is between 12V and 0V. In a preferred embodiment, the level of the threshold voltage signal VTH is between 12V and 5V.

Referring to FIG. 2, in the embodiment, the signal generating circuit 24 comprises a processor 240 and a digital-to-analog converter (DAC) 241 which both receive the voltage signal VS22 of 3.3V. The processor 240 generates a digital signal S240. The DAC 241 receives the digital signal S240 and converts the digital signal S240 to an analog signal S241. The amplifier 25 receives the analog signal S241. In the embodiment, whether the amplifier 25 amplifies the analog signal S241 to generate an amplified signal S25 is determined according to the control signal S23 from the controller 23. The detailed operations of the controller 23 and the amplifier 25 will be described in the following.

When the power source 20 is turned on, the power source 20 provides the supply voltage signal VS20 of 12V. Since the level of the supply voltage signal VS20 is higher than the level of the threshold voltage signal VTH, the controller 23 de-asserts the control signal S23 by comparing the supply voltage signal VS20 and the threshold voltage signal VTH. At this time, the amplifier 25 amplifies the analog signal S241 to generate the amplified signal S25 according to the de-asserted control signal S23. The speaker 26 receives the amplified signal S25 and produces sound according to the amplified signal S25.

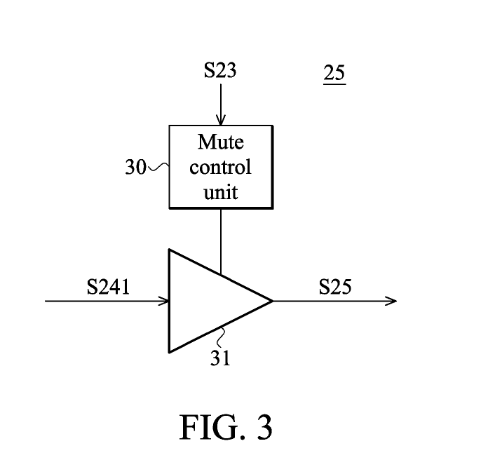

Referring to FIG. 3, in the embodiment, the amplifier 25 may comprises a mute control unit 30 and an amplifying unit 31. When receiving the de-asserted control signal S23, the mute control unit 30 is disabled, so that the amplifying unit 31 can amplify the analog signal S241 to generate the amplified signal S25 for the speaker 26.

When the power source 20 is turned off, the power source 20 stops providing the supply voltage signal VS20 of 12V, for example when the electric plug of the audio output device 2 is pulled out of the socket. In this situation, the level of the supply voltage signal VS20 is reduced from 12V to 0V. In the duration of that the level of the supply voltage signal VS20 is reduced from 12V to 0V, when the level of the supply voltage signal VS20 is lower than the level of the threshold voltage signal VTH, the controller 23 asserts the control signal S23 by comparing the supply voltage signal VS20 and the threshold voltage signal VTH. At this time, the amplifier 25 stops amplifying the analog signal S241 and generating the amplified signal S25 according to the asserted control signal S23. Thus, the speaker 26 does not receive any signal from the amplifier 25 and does not produce sound.

Referring to FIG. 3, when receiving the asserted control signal S23, the mute control unit 30 is enabled, so that the amplifying unit 31 is disabled by the mute control unit 30 and stops generating the amplified signal S25 for the speaker 26.

According to the above described embodiment, the threshold voltage signal VTH is set between 12V and 0V. In the duration of that the level of the supply voltage signal VS20 is reduced from 12V to 0V, before the level of the supply voltage signal VS20 becomes 0V, the controller 23 directs the asserted control signal S23 for the amplifier 25 to stop generating the amplified signal S25, and the speaker 26 does not produce any more sound. Thus, when the level of the supply voltage signal VS20 is at 0V, the speaker 26 does not produce pump noise.

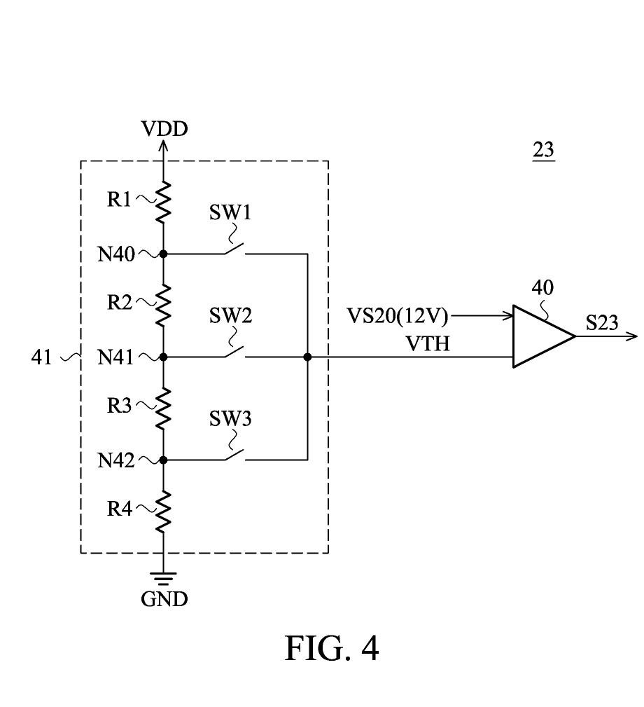

FIG. 4 shows an exemplary embodiment of the controller 23 of FIG. 2. Referring to FIG. 4, the controller 23 comprises a comparison unit 40 and a voltage dividing unit 41. The comparison unit 40 has a first input terminal for receiving the supply voltage signal VS20 and a second input terminal for receiving the threshold voltage signal VTH. The comparison unit 40 compares the supply voltage signal VS20 with the threshold voltage signal VTH and generates the control signal S23 to the amplifier 25. The voltage dividing unit 41 is coupled between a voltage source VDD and a ground GND and provides the threshold voltage signal VTH.

Referring to FIG. 4, the voltage dividing unit 41 comprises a plurality of resistors and a plurality of switches. In the embodiment, four resistors R1-R4 and three switches SW1-SW3 are given as an example. The resistors R1-R4 are coupled in series between the voltage source VDD and the ground GND. In the embodiment, the voltage source VDD provides a voltage signal which has the same level as the supply voltage signal VS20 when the power source 20 is turned on. In other words, the voltage source VDD provides a voltage signal of 12V. The resistors R1-R4 divide the voltage signal of 12V and generate three voltage signals having different levels respectively at the connection nodes N40-N42 between the resistors R1-R4. Each of the switches SW1-SW3 is coupled to one connection node between the two adjacent resistors and the second input terminal of the comparison unit 40. For example, the switch SW1 is coupled between the connection node N40 between the adjacent resistors R1-R2 and the second input terminal of the comparison unit 40. Among the switches SW1-SW3, one switch is tuned on at a time. The voltage signal at the corresponding connection node is transmitted to the second input terminal of the comparison unit 40 to serve as the threshold voltage signal VTH. For example, when the switch SW2 is turned on, the voltage signal at the connection node N41 serves as the threshold voltage signal VTH. In the embodiment, the turned-on and turned-off states of the switches SW1-SW3 can be controlled by the processor 240. Which switch is tuned on at a time is determined by system requirements and/or the specification of the power source 20.

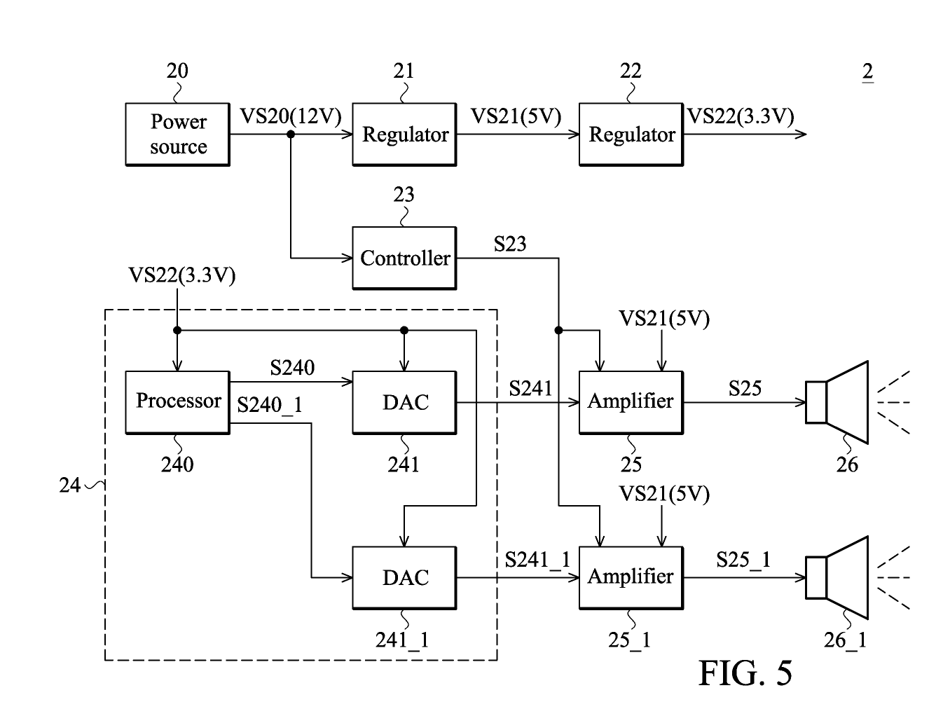

In the embodiment of FIG. 2, the signal generating circuit 24 may comprises a plurality of DACs. In the following, two DACs are given as an example. As shown in FIG. 5, in addition to the DAC 241, the signal generating circuit 24 further comprises a DAC 241_1 which is also supplied by the voltage signal VS22 of 3.3V. The DAC 241_1 is coupled to the processor 240. The processor 240 further generates a digital signal S240_1 for the DAC 241_1. The DAC 241_1 converts the digital signal S240_1 to an analog signal S241_1. For the two DACs in the signal generating circuit 24, the audio output device 2 further comprises one set comprising an amplifier 25_1 and a speaker 26_1 for the DAC 241_1. The amplifier 25_1 and the speaker 26_1 perform the same operations as the amplifier 25 and the speaker 26 respectively. The control signal S23 is used to control both of the amplifiers 25 and 25_1.

When the power source 20 is turned on to provide the supply voltage signal VS20 of 12V, both of the amplifiers 25 and 25_1 amplify the analog signal S241 and S241_1 to generate amplified signals S25 and S25_1 according to the de-asserted control signal S23, respectively. The speakers 26 and 26_1 receive the amplified signals S25 and S25_1 and produces sound according to the amplified signals S25 and S25_1, respectively.

In the duration of that the level of the supply voltage signal VS20 is reduced from 12V to 0V, when the level of the supply voltage signal VS20 is lower than the level of the threshold voltage signal VTH, both of the amplifiers 25 and 25_1 stop amplifying the analog signal S241 and S241_1 and generating the amplified signals S25 and S25_1 according to the asserted control signal S23, respectively. The speakers 26 and 26_1 do not receive any signal from the amplifiers 25 and 25_1 and thus do not produce sound. Thus, when the level of the supply voltage signal VS20 is at 0V, the speakers 26 and 26_1 do not produce pump noise.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An audio output device comprising:
a power source for providing a supply voltage signal;
a controller for receiving the supply voltage signal, comparing the supply voltage signal with a threshold voltage signal, and generating a control signal according to the comparison result;
a signal generating circuit for generating a first analog signal; and
a first amplifier for receiving the first analog signal and generating a first amplified signal according to the control signal.

2. The audio output device as claimed in claim 1, wherein when a level of the supply voltage signal is lower than a level of the threshold voltage signal, the control signal is asserted and the first amplifier does not generate the first amplified signal according to the asserted control signal.

3. The audio output device as claimed in claim 2, wherein when the level of the supply voltage signal is higher than the level of the threshold voltage signal, the control signal is de-asserted and the first amplifier generates the first amplified signal according to the de-asserted control signal.

4. The audio output device as claimed in claim 2, wherein the first amplifier comprises:
a mute control unit, enabled by the asserted control signal, for receiving the control signal ; and
an amplifying unit for receiving the first analog signal and amplifying the first analog signal to generate the first amplified signal;
wherein when the mute control unit is enabled, the amplifying unit is disabled by the mute control unit and does not generate the first amplified signal.

5. The audio output device as claimed in claim 1, wherein the controller comprises a comparison unit having a first input terminal for receiving the supply voltage signal and a second input terminal for receiving the threshold voltage signal, and the comparison unit compares the supply voltage signal with the threshold voltage signal and generates the control signal.

6. The audio output device as claimed in claim 5, wherein the controller further comprises a voltage dividing unit, coupled between a voltage source and a ground, for providing the threshold voltage signal.

7. The audio output device as claimed in claim 6, wherein the voltage dividing unit comprises:
a plurality of resistors coupled in series between the voltage source and the ground; and
a plurality of switches, each coupled to a connection node between the two adjacent resistors and the second input terminal of the comparison unit;
wherein one of the switches is turned on at a time, and a voltage signal at the corresponding connection node is transmitted to the second input terminal of the comparison unit to serve as the threshold voltage signal.

8. The audio output device as claimed in claim 1 further comprising a speaker for receiving the first amplified signal and producing sound according to the first amplified signal.

9. The audio output device as claimed in claim 1, wherein the signal generating circuit further generates a second analog signal, and the audio output device further comprises:
a second amplifier for receiving the second analog signal and amplifying the second analog signal to generate a second amplified signal according to the control signal.

10. The audio output device as claimed in claim 1, wherein the signal generating circuit comprises:
a processor for generating a digital signal; and
a digital-to-analog converter for receiving the digital signal and converting the digital signal to the first analog signal.

11. An audio output device comprising:
a power source for providing a supply voltage signal;
a signal generating circuit for generating a first analog signal;
a first amplifier for receiving the first analog signal; and
a controller for receiving the supply voltage signal, comparing the supply voltage signal with a threshold voltage signal, and generating a control signal according to the comparison result;
wherein when a level of the supply voltage signal is higher than a level of the threshold voltage signal, the first amplifier generates a first amplified signal according to the control signal; and
wherein when the level of the supply voltage signal is lower than the level of the threshold voltage signal, the first amplifier stops generating the first amplified signal according to the control signal.

12. The audio output device as claimed in claim 11, wherein the first amplifier comprises:
a mute control unit for receiving the control signal; and
an amplifying unit for receiving the first analog signal;
wherein when the level of the supply voltage signal is higher than the level of the threshold voltage signal, the mute control unit is disabled according to the control signal, and the amplifying unit amplifies the first analog signal to generate the first amplified signal; and
wherein when the level of the supply voltage signal is lower than the level of the threshold voltage signal, the mute control unit is enabled according to the control signal, and the amplifying unit stops generating the first amplified signal.

13. The audio output device as claimed in claim 11, wherein the controller comprises a comparison unit having a first input terminal for receiving the supply voltage signal and a second input terminal for receiving the threshold voltage signal, and the comparison unit compares the supply voltage signal with the threshold voltage signal and generates the control signal.

14. The audio output device as claimed in claim 13, wherein the controller further comprises a voltage dividing unit, coupled between a voltage source and a ground, for providing the threshold voltage signal.

15. The audio output device as claimed in claim 14, wherein the voltage dividing unit comprises:
a plurality of resistors coupled in series between the voltage source and the ground; and
a plurality of switches, each coupled to a connection node between the two adjacent resistors and the second input terminal of the comparison unit;
wherein one of the switches is turned on at a time, and a voltage signal at the corresponding connection node is transmitted to the second input terminal of the comparison unit to serve as the threshold voltage signal.

16. The audio output device as claimed in claim 11 further comprising a speaker for receiving the first amplified signal and producing sound according to the first amplified signal.

17. The audio output device as claimed in claim 11, wherein the signal generating circuit further generates a second analog signal, and the audio output device further comprises:
a second amplifier for receiving the second analog signal;
wherein when the level of the supply voltage signal is higher than the level of the threshold voltage signal, the second amplifier amplifies the second analog signal to generate a second amplified signal according to the control signal; and
wherein when the level of the supply voltage signal is lower than the level of the threshold voltage signal, the second amplifier stops generating the second amplified signal according to the control signal.

18. The audio output device as claimed in claim 11, wherein the signal generating circuit comprises:
a processor for generating a digital signal; and
a digital-to-analog converter for receiving the digital signal and converting the digital signal to the first analog signal.
